(19) United States
(12) Patent Application Publication
(10) Pub. No.: US 2026/0212834 A1
(43) Pub. Date: Jul. 23, 2026

(54) Display Device

(71) Applicant: LG Display Co., Ltd., Seoul (KR)

(72) Inventors: Hyun Seung Kim, Paju-si (KR); Ji Su Han, Paju-si (KR)

(21) Appl. No.: 19/387,527

(22) Filed: Nov. 12, 2025

(30) Foreign Application Priority Data
Jan. 20, 2025 (KR) 10-2025-0008067

(51) Int. Cl. G09G 3/36; G09G 3/3225

(52) U.S. Cl. CPC G09G 3/36; G09G 3/3225; G09G 2300/0842; G09G 2320/0238; G09G 2320/0242; G09G 2320/068; G09G 2358/00

(57) ABSTRACT

Disclosed is a display device. The display device includes a light-emitting element configured to emit light, a Pancharatnam-Berry lens disposed on the light-emitting element, the Pancharatnam-Berry lens being configured to convert pixel light emitted by the light-emitting element into light having a gradually increasing width and light having a gradually decreasing width, an active shutter disposed on the Pancharatnam-Berry lens, the active shutter being configured change the polarization state of light incident from the Pancharatnam-Berry lens depending on whether a mode control voltage is applied from the outside and to output the same, and a polarizer disposed on the active shutter, the polarizer being configured to transmit or absorb the light output from the active shutter.

### CROSS-REFERENCE TO RELATED APPLICATIONS

This application claims the benefit of Republic of Korea Patent Application No. 10-2025-0008067, filed on Jan. 20, 2025, which is hereby incorporated by reference as if fully set forth herein.

### BACKGROUND OF THE DISCLOSURE

### Field of the Disclosure

The present disclosure relates to a display device.

### Discussion of the Related Art

As information technology advances, the market for display devices, which are the medium of connection between users and information, is growing. Accordingly, the use of display devices, such as a light-emitting display device (LED), a quantum dot display device (QDD), and a liquid crystal display device (LCD), is increasing.

The aforesaid display devices are configured such that, when scan signals and data signals are supplied to subpixels formed on a display panel, selected subpixels transmit light or emit light directly to display an image.

Recently, various technologies have been developed to control the viewing angle of a display device. For example, conventionally, a louver film and a polymer dispersed liquid crystal (PDLC) are stacked, and voltage is or is not applied to the PDLC to narrow or widen the viewing angle of an image displayed on the display device.

However, this technology has the problem that light efficiency is reduced by the louver film, which reduces the luminance of the image.

### SUMMARY OF THE DISCLOSURE

Accordingly, the present disclosure is directed to a display device that substantially obviates one or more problems due to limitations and disadvantages of the related art.

It is an object of the present disclosure to provide display device capable of controlling the viewing angle while minimizing a reduction in luminance.

Objects of the present disclosure devised to solve the problems are not limited to the aforementioned objects, and other unmentioned objects will be clearly understood by those skilled in the art based on the following detailed description of the present disclosure.

A display device according to an embodiment of the present disclosure includes a light-emitting element configured to emit light, a Pancharatnam-Berry lens disposed on the light-emitting element, the Pancharatnam-Berry lens being configured to convert pixel light emitted by the light-emitting element into light having a gradually increasing width and into light having a gradually decreasing width, an active shutter disposed on the Pancharatnam-Berry lens, the active shutter being configured change the polarization state of light incident from the Pancharatnam-Berry lens depending on whether a mode control voltage is applied from the outside and to output the same, and a polarizer disposed on the active shutter, the polarizer being configured to transmit or absorb the light output from the active shutter.

The Pancharatnam-Berry lens may convert pixel light incident from the light-emitting element OLED and having a first width into a wide view light having first circular polarization rotating in a first direction and a width gradually increasing from the first width, or the Pancharatnam-Berry lens converts pixel light into a narrow view light having second circular polarization rotating in a second direction opposite the first direction and a width gradually decreasing from the first width.

The Pancharatnam-Berry lens may include a reactive mesogen film having reactive mesogen aligned on an alignment film in a predetermined pattern.

The polarizer may transmit light having first linear polarization that oscillates in a first direction and may absorb light having second linear polarization that oscillates in a second direction different from the first direction, among light incident from the active shutter.

The active shutter may include liquid crystal molecules aligned on the alignment film at a predetermined alignment angle, the alignment angle being changed according to the mode control voltage, and the liquid crystal molecules may have a first alignment angle with respect to the alignment film when the mode control voltage has a turn-off voltage and may have a second alignment angle different from the first alignment angle with respect to the alignment film when the mode control voltage has a turn-on voltage.

When the mode control voltage has a turn-off voltage, the active shutter may output incident light in the state in which the wavelength of the incident light is delayed by a first phase by causing the liquid crystal molecules to have the first alignment angle, and when the mode control voltage has a turn-on voltage, the active shutter may output incident light in the state in which the wavelength of the incident light is delayed by a second phase by causing the liquid crystal molecules to have the second alignment angle.

The active shutter may change the pixel light from circular polarization to linear polarization or may reverse the rotation direction of the circular polarization of the pixel light depending on whether the mode control voltage is applied.

The active shutter may phase-delay the wavelength of incident light by ¾ wavelength when the mode control voltage has a turn-off voltage, and the active shutter may phase-delay the wavelength of the incident light by ¼ wavelength when the mode control voltage is applied.

When the mode control voltage has a turn-off voltage, the active shutter may polarize the first circular polarization into the first linear polarization and may convert the second circular polarization into the second linear polarization, and when the mode control voltage has a turn-on voltage, the active shutter may polarize the first circular polarization into the second linear polarization and may convert the second circular polarization into the first linear polarization.

The display device may further include a quarter wave plate provided between the polarizer and the active shutter, wherein the active shutter may not delay the wavelength of incident light when the mode control voltage has a turn-on voltage, and the active shutter may phase-delay the wavelength of the incident light by ½ wavelength when the mode control voltage has a turn-off voltage.

The active shutter may maintain the circular polarization state of incident light having circular polarization when the mode control voltage has a turn-on voltage, and the active shutter may reverse the rotation direction of the circular polarization when the mode control voltage has a turn-off voltage.

The light-emitting element may be disposed on a front surface of a substrate, and the Pancharatnam-Berry lens, the active shutter, and the polarizer may be sequentially disposed on the light-emitting element.

The light-emitting element may be disposed on the front surface of the substrate, the Pancharatnam-Berry lens may be disposed between the light-emitting element and the substrate, and the active shutter and the polarizer may be disposed on a rear surface of the substrate.

In another embodiment, a display device comprises a light-emitting element configured to emit light; a Pancharatnam-Berry lens disposed on the light-emitting element; an active shutter disposed on the Pancharatnam-Berry lens, the active shutter configured to change a polarization state of light incident from the Pancharatnam-Berry lens responsive to a mode control voltage applied to the active shutter; and a polarizer disposed on the active shutter, the polarizer configured to transmit or absorb light output from the active shutter, wherein the light transmitted through the polarizer has a first viewing angle, responsive to the mode control voltage applied to the active shutter being in a first state, and wherein the light transmitted through the polarizer has a second viewing angle narrower than the first viewing angle, responsive to the mode control voltage applied to the active shutter being in a second state different from the first state.

Specific details of other embodiments are included in the detailed description and the drawings.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a conceptual view illustrating the configuration of a display device according to an embodiment of the present disclosure;

FIG. 2 is a view illustrating an example of a pixel equivalent circuit applied to each subpixel shown in FIG. 1;

FIG. 3 is a sectional view illustrating a first embodiment of the structure of a display panel shown in FIG. 1;

FIGS. 4A to 4C are views illustrating a Pancharatnam-Berry lens shown in FIG. 3;

FIGS. 5A to 5C are views illustrating an active shutter shown in FIG. 3;

FIG. 6 is a view illustrating a change in polarization of the display panel according to FIG. 3;

FIGS. 7A and 7B are views illustrating a change in luminance according to a change in viewing angle when the mode control voltage of the active shutter is turned on or off;

FIG. 8 is a view illustrating a share mode and a privacy mode of a displayed image according to a change in viewing angle when the mode control voltage of the active shutter is turned on or off;

FIG. 9 is a sectional view illustrating a second embodiment of the structure of the display panel shown in FIG. 1;

FIG. 10 is a view illustrating a change in polarization of the display panel according to FIG. 9; and

FIG. 11 is a view illustrating an example of the structure of a bottom emission type display panel.

### DETAILED DESCRIPTION OF THE DISCLOSURE

Hereinafter, embodiments will be described with reference to the drawings.

The same reference numerals denote the same elements. In addition, some of the drawings may be exaggerated for effective explanation of the thickness, ratio, and dimensions of elements. The scale of the elements shown in the drawings is different from the actual scale for convenience of description, and is not limited to the scale shown in the drawings.

In this specification, when an element (or area, layer, part, etc.) is said to be “on”, “connected to”, or “coupled to” another element, this means that the element may be directly connected/coupled to the other element or that a third element may be disposed therebetween.

“And/or” includes all combinations of associated configurations that can be defined.

It will be understood that, although the terms “first”, “second”, etc. may be used herein to describe various elements, the elements should not be understood to be limited by these terms, which are used only to distinguish one element from another. For example, within the scope defined by the present disclosure, a first element may be referred to as a second element, and similarly, a second element may be referred to as a first element. A singular representation may include a plural representation unless it represents a definitely different meaning from the context.

Terms such as “below”, “lower”, “above”, and “upper” are used to describe the relationship between the configurations shown in the drawings. The terms are relative concepts and are described based on the direction indicated in the drawings. For example, unless “directly” or “directly” is used, one or more other parts may be located between two parts. Spatially relative terms such as “below” (beneath), “lower”, “above”, and “upper” may be used to facilitate description of the relationship between one device or element and another device or element as shown in the drawings. Therefore, for example, “below” and “lower” with respect to a first element may be in the opposite direction to “above” and “upper” with respect to the first element.

Spatially relative terms should be understood as including different directions of a device when used or in operation, in addition to the directions shown in the drawings. For example, if a device shown in the drawing is turned upside down, a device described as “below” or “beneath” another device may be located “above” the other device. Therefore, the exemplary term “below” may include both the downward and upward directions.

It will be further understood that the terms “comprises”, “has”, etc., when used in this specification, specify the presence of stated features, numbers, steps, operations, elements, components, or combinations thereof, but do not preclude the presence or addition of one or more other features, numbers, steps, operations, elements, components, or combinations thereof.

The respective features of the various embodiments of the present disclosure may be partially or wholly coupled to and combined with each other, and various technical linkages therebetween and operation methods thereof are possible. These various embodiments may be performed independently of each other, or may be performed in association with each other.

Hereinafter, a display device according to the present disclosure will be described with reference to the accompanying drawings and embodiments.

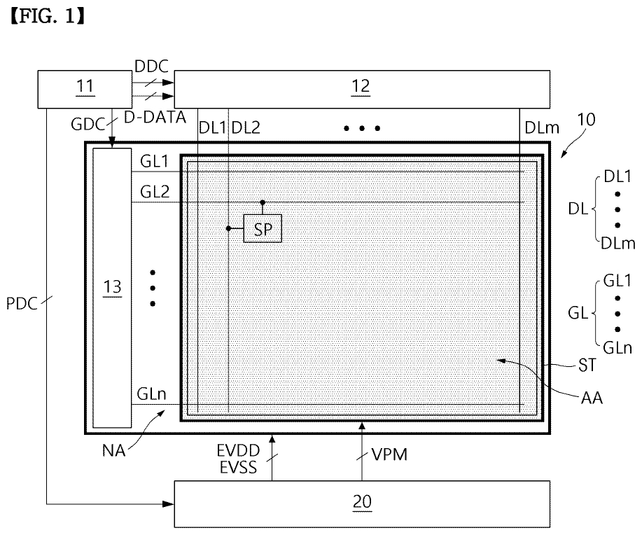

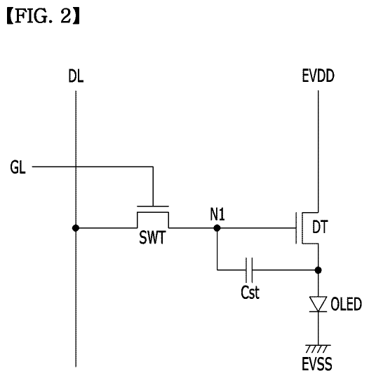

FIG. 1 is a conceptual view illustrating the configuration of a display device according to an embodiment of the present disclosure, and FIG. 2 is a view illustrating an example of a pixel equivalent circuit applied to each subpixel SP shown in FIG. 1.

As shown in FIG. 1, the display device according to the embodiment of the present disclosure may include a display panel 10, a timing controller 11, a data driver 12, a gate driver 13, a power supply 20, and an active shutter ST.

FIG. 1 shows an example in which the timing controller 11, the data driver 12, and the power supply 20 are separately provided, but, unlike FIG. 1, the timing controller 11, the data driver 12, and the power supply 20 may be entirely or partially integrated in a driving integrated circuit. In FIG. 1, the data driver 12, the gate driver 13, and the power supply 20 may be provided with a panel driving circuit for driving the display panel 10.

The display panel 10 may include an active area AA and a non-active area NA.

As shown in FIG. 1, the gate driver 13 may be provided in the non-active area NA of the display panel 10 in a gate driver in panel (GIP) mode. For example, the gate driver 13 according to the present disclosure may be formed directly on a substrate of the display panel 10. However, the present disclosure is not limited thereto, and the gate driver 13 may be distributed in the active area AA of the display panel 10 together with a plurality of subpixels SP, unlike FIG. 1.

The active area AA may be an area for displaying an image. A plurality of subpixels SP may be disposed in the active area AA, and an image may be displayed using the plurality of subpixels SP. The area in which the plurality of subpixels SP is disposed may be the active area AA, and the area other than the active area AA may be the non-active area NA.

The plurality of subpixels SP disposed in the active area AA may display different colors, such as red (R), green G, or blue (B).

The non-active area NA may be disposed at the edge surrounding the active area AA that displays the image. At least one panel driving circuit configured to drive the plurality of subpixels SP may be disposed in the non-active area NA.

At least one of the plurality of subpixels SP may include, for example, a switching transistor SWT, a driving transistor DT, a capacitor Cst, and a light-emitting element OLED, as shown in FIG. 2.

A first electrode of the switching transistor SWT may be electrically connected to a data line DL to receive a data voltage, a second electrode of the switching transistor SWT may be electrically connected to a first node N1, and a gate electrode of the switching transistor SWT may be electrically connected to a gate line GL to receive a scan signal. The switching transistor SWT may transmit the data voltage supplied via the data line DL to the first node N1 in response to the scan signal supplied via the gate line GL.

A first electrode of the driving transistor DT may receive a high-potential driving voltage (EVDD), and a second electrode of the driving transistor DT may be electrically connected to a first electrode of the light-emitting element OLED. The driving transistor DT may generate a driving current flowing through the light-emitting element OLED in response to the voltage applied to the gate electrode from the first node N1.

One end of the capacitor Cst may be electrically connected to the first node N1 and the other end of the capacitor Cst may be electrically connected to the second electrode of the driving transistor DT, and the capacitor Cst may store the voltage applied to the first node N1.

The light-emitting element OLED may output light corresponding to the driving current Ids. The light-emitting element OLED may emit light corresponding to any one of red (R), green G, blue (B), and white (W). Hereinafter, the light emitted by the light-emitting element OLED will be referred to as pixel light.

The pixel light may be generated by an emission layer provided in the light-emitting element OLED. The emission layer may be implemented to emit light of the same color for each pixel, such as white light, or to emit light of different colors for each subpixel SP, such as red (R), green G, or blue (B) light.

In addition, although not shown in FIG. 2, the subpixel SP may be further provided therein with a compensation circuit (not shown) configured to compensate for the threshold voltage of the driving transistor DT. The compensation circuit may include at least one transistor connected to the driving transistor DT and may be provided in the subpixel SP.

In FIG. 1, the timing controller 11 may supply digital image data D-DATA transmitted from a host system (not shown) to the data driver 12.

The timing controller 11 may receive timing signals, such as a vertical sync signal, a horizontal sync signal, a data enable signal, and a dot clock signal, from the host system and may generate timing control signals for controlling the operation timing of the panel driving circuit.

The timing control signals may include a gate timing control signal GDC for controlling the operation timing of the gate driving unit 13, a data timing control signal DDC for controlling the operation timing of the data driving unit 12, and a power timing control signal PDC for controlling the operation timing of the power supply 20.

The data driver 12 may be connected to the plurality of subpixels SP via data lines DL (DL1 to DLm). The data driver 12 may generate data voltages, which are analog signals required to drive the plurality of subpixels SP, based on the digital image data D-DATA received from the timing controller 11 and may supply the same to the data lines DL.

The data driver 12 may convert the digital image data D-DATA received from the timing controller 11 into parallel data by sampling and latching based on the data timing control signal DDC, may convert the digital image data D-DATA into analog data voltages according to gamma compensation voltages through a digital-to-analog converter (hereinafter referred to as a DAC), and may supply the analog data voltages to the plurality of subpixels SP through the data lines DL. The analog data voltages may be analog voltage values of different voltage levels corresponding to gray scales of an image to be expressed by the plurality of subpixels SP.

The data driver 12 may output the data voltages to the plurality of subpixels SP according to the data timing control signal DDC. The data driver 12 may include a plurality of source driver integrated circuits. The source driver integrated circuit may include a shift register, a latch, a level shifter, a DAC, and an output buffer.

The gate driver 13 may generate scan signals based on the gate timing control signal GDC and supply the same to the plurality of subpixels SP via gate lines GL (GL1 to GLn). In addition, the gate driver 13 may generate a carry signal CRY to be supplied to a plurality of stages provided therein such that the scan signals are supplied sequentially.

For example, the gate driver 13 may generate a carry signal CRY based on a carry clock signal supplied as a type of gate timing control signal GDC from the timing controller 11 and may generate a scan signal based on a scan clock signal supplied as a type of gate timing control signal GDC.

The power supply 20 may process an input power according to the power timing control signal PDC and supply the driving powers EVDD and EVSS for driving the plurality of subpixels SP. In some cases, the power supply 20 may also supply a driving power required for the operation of the gate driver 13.

In addition, the power supply 20 may supply a mode control voltage VPM required for the operation of the active shutter ST disposed on the display panel 10.

The active shutter ST may perform control such that the image displayed in the active area AA has a wide viewing angle or a narrow viewing angle depending on whether the mode control voltage VPM is applied. For example, the active shutter ST may perform control such that the image in the active area AA has a wide viewing angle when the mode control voltage VPM is not applied, and may perform control such that the image in the active area AA has a narrow viewing angle when the mode control voltage VPM is applied.

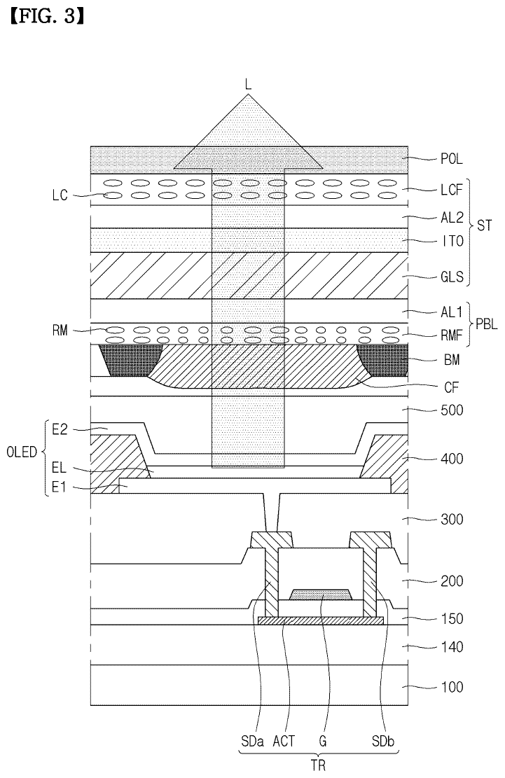

Hereinafter, the specific configuration of the display panel 10 provided with the active shutter ST and the operation of the active shutter ST will be described with reference to FIG. 3 and subsequent figures.

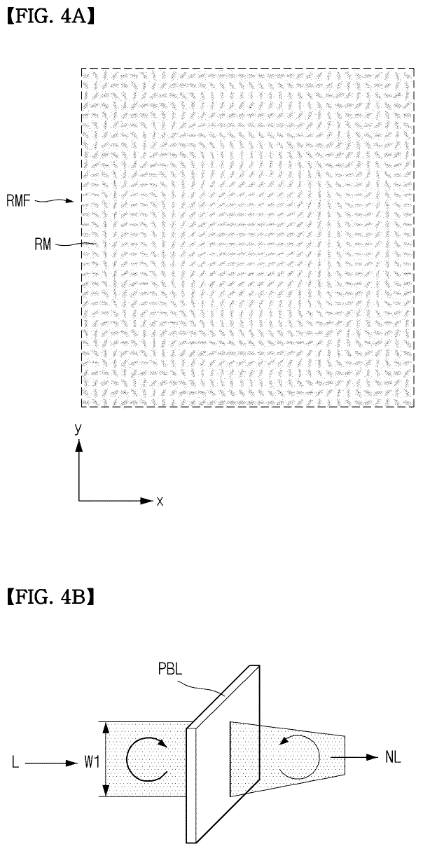

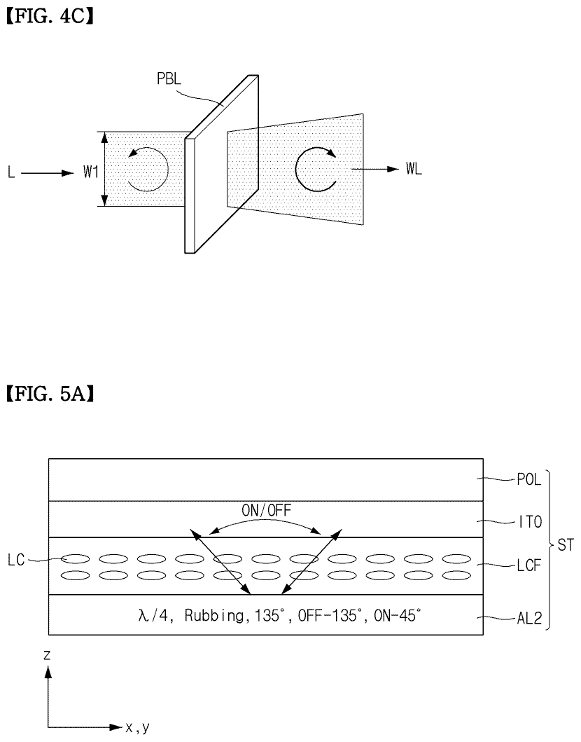

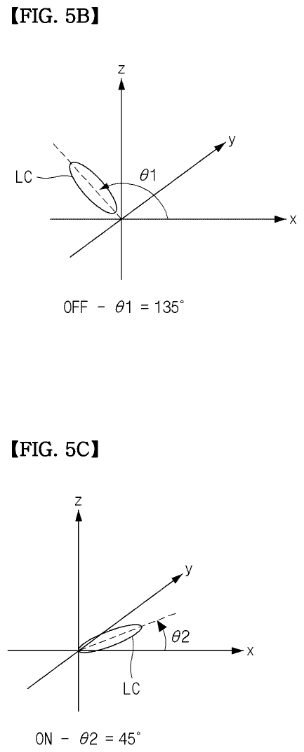

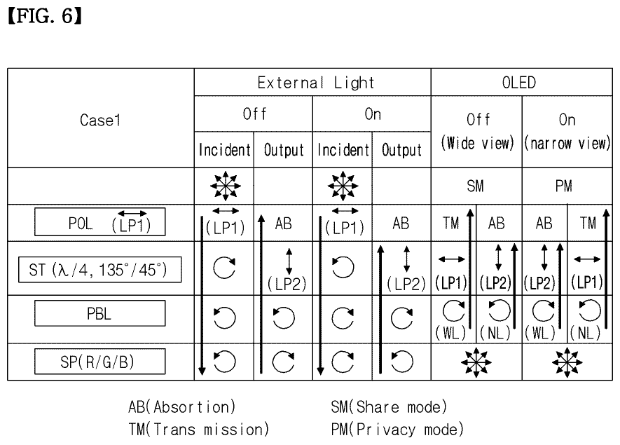

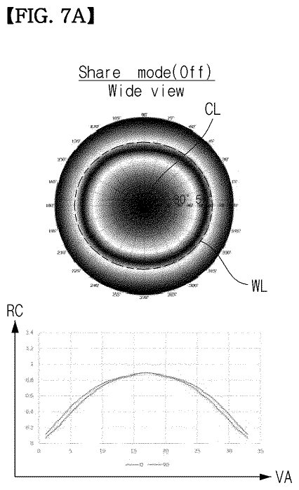

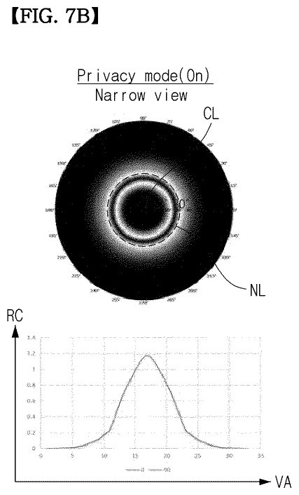

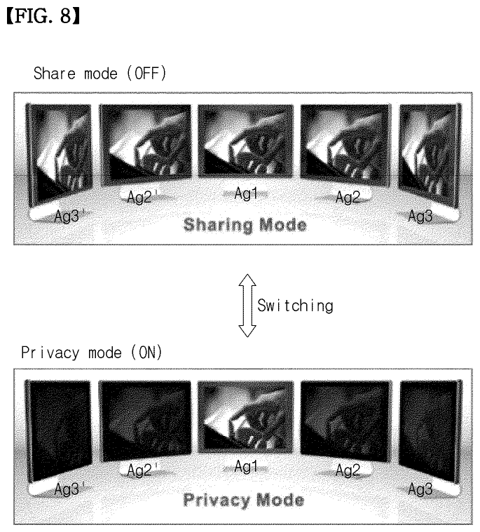

FIG. 3 is a sectional view illustrating a first embodiment of the structure of the display panel shown in FIG. 1, FIGS. 4A to 4C are views illustrating a Pancharatnam-Berry lens shown in FIG. 3, FIGS. 5A to 5C are views illustrating an active shutter shown in FIG. 3, FIG. 6 is a view illustrating a change in polarization of the display panel according to FIG. 3, FIGS. 7A and 7B are views illustrating a change in luminance according to a change in viewing angle when the mode control voltage of the active shutter is turned on or off, and FIG. 8 is a view illustrating a share mode and a privacy mode of a displayed image according to a change in viewing angle when the mode control voltage of the active shutter is turned on or off.

As shown in FIG. 3, the display panel according to the first embodiment of the present disclosure may include a substrate 100, a buffer layer 140, a gate insulating film 150, an interlayer insulating film 200, a planarization film 300, a transistor TR, a bank 400, a light-emitting element OLED, an encapsulation layer 500, a black matrix BM, a color filter CF, a Pancharatnam-Berry lens PBL, an active shutter ST, and a polarizer POL.

In FIG. 3, the transistor TR may be any one of a switching transistor SWT and a driving transistor DT, and the transistor TR in FIG. 3 may be the driving transistor DT shown in FIG. 2. The sectional structure of the display device of FIG. 3 is shown for easy understanding of the present disclosure, and the present disclosure is not necessarily limited thereto.

The display panel shown in FIG. 3 may have a top emission structure.

The substrate 100 may be made of a flexible plastic material so as to have flexible characteristics, and may include a thin, flexible glass material.

The buffer layer 140 may be provided on the insulating film 110. The buffer layer 140 may include an inorganic insulating material such as silicon oxide (SiO) or silicon nitride (SiN).

The transistor TR may be disposed on the buffer layer 140. For example, the transistor TR may generate a driving current flowing through the light-emitting element OLED in response to the voltage applied to a gate electrode G. The transistor TR may include a gate electrode G, an active layer ACT, a source electrode SDa, and a drain electrode SDb.

The gate electrode G may receive a data voltage from the first node N1 of FIG. 2.

The active layer ACT may include an oxide semiconductor such as indium-gallium-zinc-oxide (IGZO), but the present disclosure is not limited thereto. The active layer ACT may be located on the buffer layer 140, and the active layer ACT may include a source area, a channel area, and a drain area, which are not shown. The channel area may be located in the active layer ACT while overlapping the gate electrode G, and the source area and the drain area may be located in the active layer ACT outside the gate electrode G that does not overlap the gate electrode G. Each of the source and drain areas may have higher electrical conductivity than the channel area, and the channel area may form a channel in response to the voltage applied to the gate electrode.

The source electrode SDa may be in contact with the source area, and the drain electrode SDb may be in contact with the drain area.

The gate insulating film 150 may be stacked on the buffer layer 140 while covering the active layer ACT. The gate insulating film 150 may insulate the gate electrode G of the transistor TR and the active layer ACT from each other. The gate electrode G may be located on the gate insulating film 150.

The interlayer insulating film 200 may be located on the gate insulating film 150 so as to cover the gate electrode G of the transistor TR. The source electrode SDa and the drain electrode SDb may be located on the interlayer insulating film 200.

The source electrode SDa and the drain electrode SDb may extend through the interlayer insulating film 200 and the gate insulating film 150 and may contact the source area and the drain area of the transistor TR, respectively.

The planarization film 300 may be stacked on the interlayer insulating film 200 so as to cover the source electrode SDa and the drain electrode SDb. The planarization film 300 may eliminate a step caused by the driving circuit, and an upper surface of the planarization film 300 may have a flat surface. The planarization film 300 may include an insulating material having high fluidity.

One of the source electrode SDa and the drain electrode SDb may extend through the planarization layer 300 and may contact a first electrode E1 of the light-emitting element OLED. FIG. 3 shows an example in which the source electrode SDa contacts the first electrode E1 of the light-emitting element OLED.

The bank 400 may be located on the planarization layer 300. The bank 400 may define an emission area of each subpixel SP, and the area of each subpixel SP may be divided by the bank 400.

The bank 400 may include a light-absorbing material, and may include a black pigment such as carbon black. Accordingly, the bank 400 may absorb external light to minimize light reflectance, to further enhance blackness, and to improve contrast ratio and color accuracy, thereby further improving image quality.

The bank 400 may include an organic insulating material. The bank 400 may cover the edge of the first electrode E1 (e.g., an anode). An emission layer EL and a second electrode E2 (e.g., a cathode) may be stacked on a part of the first electrode E1 exposed by the bank 400.

Therefore, the area of each of the plurality of subpixels SP defined by each emission area may be divided by the bank 400. The light-emitting element OLED may be located in the emission area, and the light-emitting element OLED may include a first electrode E1, an emission layer EL, and a second electrode E2.

As an example, the first electrode E1 may function as an anode and may include a conductive material. The first electrode E1 may have high reflectivity. For example, the first electrode E1 may include a metal such as aluminum (Al) and silver (Ag).

The emission layer EL may generate light having luminance corresponding to the voltage difference between the first electrode E1 and the second electrode E2. For example, the emission layer EL may include an emission material layer EML including an emission material. The emission material may include an organic material, an inorganic material, or a hybrid material. For example, the emitting layer EL may include an emission material layer made of an organic material.

As an example, the second electrode E2 may function as a cathode, and may include a conductive material. The second electrode E2 may include a material different from the first electrode E1. For example, the second electrode E2 may be a transparent electrode made of a transparent conductive material (transparent conductive oxide, TCO) such as ITO and IZO. The second electrode E2 may have higher transmittance than the first electrode E1.

If the organic light-emitting element OLED is configured as described above, the pixel light emitted from the emission layer may be output in a direction toward a front surface of the substrate. As shown in FIG. 3, in the state in which the light-emitting element OLED is located on the substrate, the direction opposite the direction from the light-emitting element OLED to the substrate is referred to as a forward direction, and the direction toward the substrate is referred to as a rearward direction.

The encapsulation layer 500 may be disposed on the second electrode E2 of the emission layer EL, and may perform an encapsulation function to prevent damage to the light-emitting elements OLED due to external impact and moisture.

The encapsulation layer 500 may be configured such that inorganic insulating material layers and organic insulating material layers are alternately stacked.

The step caused by the light-emitting element OLED may be eliminated by the encapsulation layer 500, and an upper surface of the encapsulation layer 500 may be flat.

The black matrix BM may be located on the encapsulation layer 500, and may include a light-absorbing material, for example, a black pigment. The black matrix BM may overlap the bank 400.

The color filter CF may be located between the black matrices BM. The color filter CF may include a pigment that displays the same color as the color emitted by the emission layer of each subpixel SP. For example, a red subpixel SP may be provided with a red color filter CF that expresses the same color as red emitted by the emission layer, and a green subpixel SP may be provided with a green color filter CF, and a blue subpixel SP may be provided with a blue color filter CF.

The Pancharatnam-Berry lens PBL may be disposed on the color filter CF. The Pancharatnam-Berry lens PBL may convert pixel light incident from a polarized liquid crystal light-emitting element OLED into light having a gradually increasing width and into light having a gradually decreasing width.

The Pancharatnam-Berry lens PBL may include a first alignment film AL1 and a reactive mesogen film RMF having reactive mesogen RM molecules on the first alignment film AL1. FIG. 3 shows an example in which the reactive mesogen film RMF is located on the color filter CF and the first alignment film AL1 is located on the reactive mesogen film RMF.

However, the present disclosure is not necessarily limited thereto, and, unlike FIG. 3, the first alignment film AL1 may be located on the color filter CF and the reactive mesogen film RMF may be located on the first alignment film AL1.

The first alignment film AL1 may ensure that the reactive mesogen RM molecules are aligned in a predetermined pattern direction during the formation of the reactive mesogen film RMF.

The reactive mesogen RM may be aligned on the first alignment film AL1 in a predetermined pattern, and light that passes through the reactive mesogen RM may be converted into light having a gradually increasing width or light having a gradually decreasing width according to the alignment pattern of the reactive mesogen RM.

The alignment pattern of the reactive mesogen RM and the optical conversion characteristics of the Pancharatnam-Berry lens PBL will be described later in more detail with reference to FIGS. 4A, 4B, and 4C.

The active shutter ST may be disposed on the Pancharatnam-Berry lens PBL. The active shutter ST may change the polarization state of light incident from the Pancharatnam-Berry lens PBL depending on whether the mode control voltage VPM is applied, without reducing the luminance, and may output the light.

The active shutter ST may include an insulating layer GLS, a transparent electrode ITO, a second alignment film AL2, and a liquid crystal layer LCF including liquid crystal molecules LC. FIG. 3 shows an example in which the transparent electrode ITO is located between the insulating layer GLS and the second alignment film AL2, but the present disclosure is not necessarily limited thereto, and the transparent electrode ITO may be disposed between the liquid crystal layer LCF and a polarizer POL, as shown in FIG. 5.

The insulating layer GLS may be disposed on the Pancharatnam-Berry lens PBL to insulate the transparent electrode ITO and the Pancharatnam-Berry lens PBL from each other. For example, the insulating layer GLS may include glass.

The transparent electrode ITO may receive a mode control voltage VPM for controlling the alignment angle of the liquid crystal molecules LC located in the liquid crystal layer LCF, and the transparent electrode ITO may be made of a transparent conductive material (transparent conductive oxide, TCO) such as ITO and IZO.

The second alignment film AL2 may be a film rubbed such that the liquid crystal molecules LC in the liquid crystal layer LCF are aligned on the alignment film at a predetermined alignment angle.

The alignment angle of the liquid crystal molecules LC provided in the liquid crystal layer LCF may be determined by the angle at which rubbing is performed on the surface of the second alignment film AL2. The alignment angle of the liquid crystal molecules LC may be changed by the mode control voltage VPM applied through the transparent electrode ITO.

For example, the liquid crystal molecules LC may be aligned on the second alignment film AL2 with a first alignment angle when the mode control voltage VPM is not applied, and the alignment angle may be changed to a second alignment angle by changing the alignment angle by a predetermined angle when the mode control voltage VPM is applied.

When the mode control voltage VPM has a turn-off voltage, the active shutter ST may output incident light in the state in which the wavelength of the incident light is delayed by a first phase by causing the liquid crystal molecules LC to have the first alignment angle. When the mode control voltage VPM has a turn-on voltage, the active shutter ST may output incident light in the state in which the wavelength of the incident light is delayed by a second phase by causing the liquid crystal molecules LC to have the second alignment angle.

As described above, the active shutter ST may output light incident from the Pancharatnam-Berry lens PBL in the state in which the polarization state of the incident light is changed according to a change in the alignment angle of the liquid crystal molecules LC. That is, the active shutter ST may change pixel light from circular polarization to linear polarization or reverse the rotation direction of the circular polarization of the pixel light depending on whether the mode control voltage VPM is applied.

In the first embodiment of FIGS. 3 to 8, an example in which the active shutter ST outputs incident light in the state in which circular polarization of the incident light is converted into linear polarization depending on whether the mode control voltage VPM is applied or not will be described.

The active shutter ST according to the first embodiment of the present disclosure may have a rubbing angle of 135° and a phase delay value of ±¼ wavelength (λ) according to mode voltage application. The active shutter ST will be described later in more detail with reference to FIG. 5.

The polarizer POL may be disposed on the active shutter ST and may transmit or absorb light output from the active shutter ST. For example, the polarizer POL may transmit light having first linear polarization LP1 (FIG. 6) that oscillates in a first direction and absorb light having second linear polarization LP2 (FIG. 6) that oscillates in a second direction, which is different from the first direction, among the incident light that is incident from the active shutter ST. That is, the transmission axis TA of the polarizer POL may be light having the first linear polarization LP1.

Hereinafter, the Pancharatnam-Berry lens PBL will be described in more detail with reference to FIGS. 4A, 4B, and 4C.

FIG. 4A is a plan view showing the alignment pattern of the reactive mesogen RM in the reactive mesogen film RMF provided at the Pancharatnam-Berry lens PBL, and FIGS. 4B and 4C show the light conversion characteristics of incident light having circular polarization according to the rotation direction.

As shown in FIG. 4A, the reactive mesogen RM may be aligned in the reactive mesogen film RMF in a predetermined pattern. For example, the alignment direction of the reactive mesogen RM may be continuously rotated as the reactive mesogen RM moves from the center to the periphery of the reactive mesogen film RMF. Here, the alignment direction may be the long axis direction of the reactive mesogen RM.

In addition, the alignment direction of the reactive mesogen RM located within a specific radius may be uniform, and the alignment direction may have an angular distribution determined by the distance from the center. For example, as shown in FIG. 4A, the alignment direction of the reactive mesogen RM may be rotated counterclockwise as the reactive mesogen RM moves from the center to the periphery.

The Pancharatnam-Berry lens PBL may output light having a gradually increasing or decreasing width while converting the polarization pattern of incident light by the pattern of the reactive mesogen RM shown in FIG. 4A.

For example, when left-circular polarization light having a first width and rotating in a first rotation direction, which is a clockwise direction, is incident on the Pancharatnam-Berry lens PBL, as shown in FIG. 4B, the Pancharatnam-Berry lens PBL may convert the left-circular polarization to right-circular polarization according to the pattern of the reactive mesogen RM, and may convert the right-circular polarization into a narrow view light NL having a width gradually decreasing from the first width and may output the same.

In addition, when right-circular polarization light having a first width and rotating in a second rotation direction, which is a counterclockwise direction, is incident on the Pancharatnam-Berry lens PBL, as shown in FIG. 4C, the Pancharatnam-Berry lens PBL may convert the right-circular polarization into left-circular polarization, and may convert the left-circular polarization into a wide view light WL having a width gradually increasing from the first width and may output the same.

When the Pancharatnam-Berry lens PBL receives pixel light having the first width from the light-emitting element OLED, the Pancharatnam-Berry lens PBL may convert the pixel light into a wide view light WL having first circular polarization (e.g., left-circular polarization) rotating in the first direction and having a width gradually increasing from the first width and the Pancharatnam-Berry lens PBL may convert the pixel light into a narrow view light NL having second circular polarization (e.g., right-circular polarization) rotating in the second direction and having a width gradually decreasing from the first width using the characteristics of the Pancharatnam-Berry lenses PBL described above, since the pixel light of the light-emitting element OLED is isotropic light, and may output the same.

That is, the Pancharatnam-Berry lens PBL may receive pixel light and may output both a wide view light WL having first circular polarization (e.g., left-circular polarization) and a narrow view light NL having second circular polarization (e.g., right-circular polarization). Here, the wide view light WL may increase the viewing angle of the image displayed on the display panel due to the increasing width, and the narrow view light NL may decrease the viewing angle of the image displayed on the display panel due to the decreasing width.

Hereinafter, the active shutter ST will be described in more detail with reference FIGS. 5A, 5B, and 5C.

FIG. 5A shows an example of the sectional structure of the active shutter ST, FIG. 5B shows the state in which the liquid crystal molecules LC are aligned on the second alignment film AL2 at a first alignment angle θ1 when the active shutter ST is off, and FIG. 5C shows the state in which the liquid crystal molecules LC are aligned on the second alignment film AL2 at a second alignment angle θ2 when the active shutter ST is on.

In FIGS. 5B and 5C, the x-axis may be a reference direction for rubbing, the plane formed by the x-axis and the y-axis may be the plane of the second alignment film AL2, and the z-axis may be the light traveling direction.

The alignment angle of the liquid crystal molecules LC aligned on the second alignment film AL2 may be determined by rubbing recesses formed by rubbing. For example, liquid crystal molecules LC may be aligned so as to have a first alignment angle θ1 (e.g., 135°) from the x-axis along the plane formed by the x-axis and the y-axis by the rubbing recesses on the second alignment film AL2.

When the mode control voltage VPM is not applied to the transparent electrode ITO and the active shutter ST is turned off, the liquid crystal molecules LC may be aligned at the first alignment angle θ1 (e.g., 135°), and when the mode control voltage VPM is applied to the transparent electrode ITO and the active shutter ST is turned on, the alignment angle of the liquid crystal molecules LC may be changed by a quarter wavelength by an electric field of the mode control voltage VPM, and the liquid crystal molecules LC may be aligned at the second alignment angle θ2 (e.g., 45°) from the first alignment angle θ1 (e.g., 135°).

When the liquid crystal molecules LC have the first alignment angle θ1 (e.g., 135°), the active shutter ST may output incident light in the state in which the wavelength of the incident light is delayed by a first phase, and when the liquid crystal molecules LC have the second alignment angle θ2 (e.g., 45°), the active shutter ST may output incident light in the state in which the wavelength of the incident light is delayed by a second phase, which is different from the first phase.

For example, the active shutter ST may phase-delay the wavelength of the incident light by ¾ wavelength (λ) when the mode control voltage VPM has a turn-off voltage, and may phase-delay the wavelength of the incident light by ¼ wavelength (λ) when the mode control voltage VPM has a turn-on voltage. As a result, the active shutter ST may change the wavelength of the incident light by ±¼ wavelength (λ) in a travel direction of the incident light, depending on whether the mode control voltage VPM is applied. This allows the incident light to be converted from circular polarization into linear polarization or from linear polarization into circular polarization.

More specifically, (1) when the mode control voltage VPM has a turn-off voltage, the active shutter ST may polarize first circular polarization (e.g., left-circular polarization) into first linear polarization LP1 and convert second circular polarization (e.g., right-circular polarization) into second linear polarization LP2, and (2) when the mode control voltage VPM has a turn-on voltage, the active shutter ST may polarize the first circular polarization (e.g., left-circular polarization) into the second linear polarization LP2 and convert the second circular polarization (e.g., right-circular polarization) into the first linear polarization LP1.

As such, the active shutter ST according to the present disclosure may convert the polarization state of incident light without reducing the luminance of the incident light.

In this regard, a polarization change of the display panel according to the first embodiment (case 1) of the present disclosure will be described in more detail with reference to FIG. 6.

The polarization change of the display panel shown in FIG. 6 when the transmission axis TA of the polarizer POL is light having the first linear polarization LP1 and the active shutter ST aligns the liquid crystal molecules LC at the first alignment angle θ1 (135°) when the mode control voltage VPM is turned off and aligns the liquid crystal molecules LC at the second alignment angle θ2 (45°) when the mode control voltage VPM is turned on will be described.

Accordingly, (1) when the mode control voltage VPM has a turn-off voltage, the active shutter ST may polarize first circular polarization (e.g., left-circular polarization) into first linear polarization LP1 and convert second circular polarization (e.g., right-circular polarization) into second linear polarization LP2, and (2) when the mode control voltage VPM has a turn-on voltage, the active shutter ST may polarize the first circular polarization (e.g., left-circular polarization) into the second linear polarization LP2 and convert the second circular polarization (e.g., right-circular polarization) into the first linear polarization LP1.

Specifically, when isotropic external light is incident on the display panel in the state in which the active shutter ST is turned off by the mode control voltage VPM having the turn-off voltage, the isotropic external light may be converted into light having first linear polarization LP1 while passing through the polarizer POL, may be converted into light having left-circular polarization while passing through the turned-off active shutter ST, may be converted into light having right-circular polarization while passing through the Pancharatnam-Berry lens PBL, and may be incident on the subpixel SP.

The external light having the right-circular polarization incident on the subpixel SP may be converted into light having left-circular polarization while being reflected by the electrode provided in the subpixel SP, such as the first electrode E1 of the light-emitting element OLED.

The reflected light having the left-circular polarization may be converted to right-circular polarization while passing through the Pancharatnam-Berry lens PBL, may be converted to second linear polarization LP2 while passing through the turned-off active shutter ST, and may be absorbed (AB) by the polarizer POL.

When isotropic external light is incident on the display panel in the state in which the active shutter ST is turned on by the mode control voltage VPM having the turn-on voltage, the isotropic external light may be converted into light having first linear polarization LP1 while passing through the polarizer POL, may be converted into light having right-circular polarization while passing through the turned-on active shutter ST, may be converted into light having left-circular polarization while passing through the Pancharatnam-Berry lens PBL, and may be incident on the subpixel SP.

The external light having the left-circular polarization incident on the subpixel SP may be converted into light having right-circular polarization while being reflected by the electrode provided in the subpixel SP.

The reflected light having the right-circular polarization may be converted to left-circular polarization while passing through the Pancharatnam-Berry lens PBL, may be converted to second linear polarization LP2 while pasting through the turned-on active shutter ST, and may be absorbed (AB) by the polarizer POL.

As described above, the display panel according to the present disclosure is provided with the active shutter ST, whereby it is possible to prevent reflection of external light regardless of the turn-on and turn-off of the active shutter ST.

The pixel light emitted from the light-emitting element OLED of the subpixel SP in the state in which the active shutter ST is off may be isotropic. The Pancharatnam-Berry lenses PBL may receive the isotropic pixel light from the light-emitting element OLED and output both wide view light WL having left-circular polarization and narrow view light NL having right-circular polarization.

The wide view light WL having the left-circular polarization may be converted into light having first linear polarization LP1 while passing through the turned-off active shutter ST, and may be transmitted (TM) through the polarizer POL.

The narrow view light NL having the right-circular polarization may be converted into light having second linear polarization LP2 while passing through the turned-off active shutter ST, and may be absorbed (AB) by the polarizer POL.

Accordingly, in the state in which the active shutter ST is off, the display panel may prevent the reflection of external light and output wide view light WL, whereby the display panel may be operated in a share mode SM in which the display panel displays a wide view image.

In addition, even in the state in which the active shutter ST is on, the Pancharatnam-Berry lens PBL may receive isotropic pixel light and output both wide view light WL having left-circular polarization and narrow view light NL having right-circular polarization.

The wide view light WL having the left-circular polarization may be converted into light having second linear polarization LP2 while passing through the turned-on active shutter ST, and may be absorbed (AB) by the polarizer POL.

The narrow view light NL having the right-circular polarization may be converted into light having first linear polarization LP1 while passing through the turned-on active shutter ST, and may be transmitted (TM) through the polarizer POL.

Accordingly, in the state in which the active shutter ST is on, the display panel may prevent the reflection of external light and output narrow view light NL, whereby the display panel may be operated in a privacy mode PM in which the display panel displays a narrow view image.

Hereinafter, a change in luminance according to a change in viewing angle when the mode control voltage of the active shutter ST is turned on or off will be described with reference to FIG. 7.

FIG. 7A shows a change in luminance according to a change in viewing angle when the active shutter ST is turned off and the display panel is operated in a share mode, and FIG. 7B shows a change in luminance according to a change in viewing angle when the active shutter ST is turned on and the display panel is operated in a privacy mode.

When the active shutter ST is turned off and the display panel is operated in a share mode, it can be seen that, as shown in FIG. 7A, the display panel outputs wide view light WL, whereby a decrease slope of luminance RC decreased as the viewing angle VA increases from the center CL in the light travel direction is relatively small. Accordingly, the image on the display panel may have a wide view.

However, when the active shutter ST is turned on and the display panel is operated in a privacy mode, it can be seen that, as shown in FIG. 7B, the display panel outputs narrow view light NL, whereby a decrease slope of luminance RC decreased as the viewing angle VA increases from the center CL in the light travel direction is relatively large. Accordingly, the image on the display panel may have a narrow view, which is narrower than the wide view of FIG. 7A.

Accordingly, when the active shutter ST is turned off and the display panel is operated in the share mode, as shown in FIG. 8, the luminance of the image may be maintained at a high level even if the viewing angle of the display panel increases from Ag1 to Ag3 (or Ag3′).

However, when the active shutter ST is turned on and the display panel is operated in the privacy mode, the luminance of the image may be maintained at a high level on the front surface of the display panel (Ag1), but the luminance of the image may be sharply reduced as the viewing angle increases to Ag2 (or Ag2′) to Ag3 (or Ag3′), whereby the viewing angle may be limited.

As such, the display device according to the embodiment of the present disclosure may implement the share mode and the privacy mode without reduction in luminous efficiency.

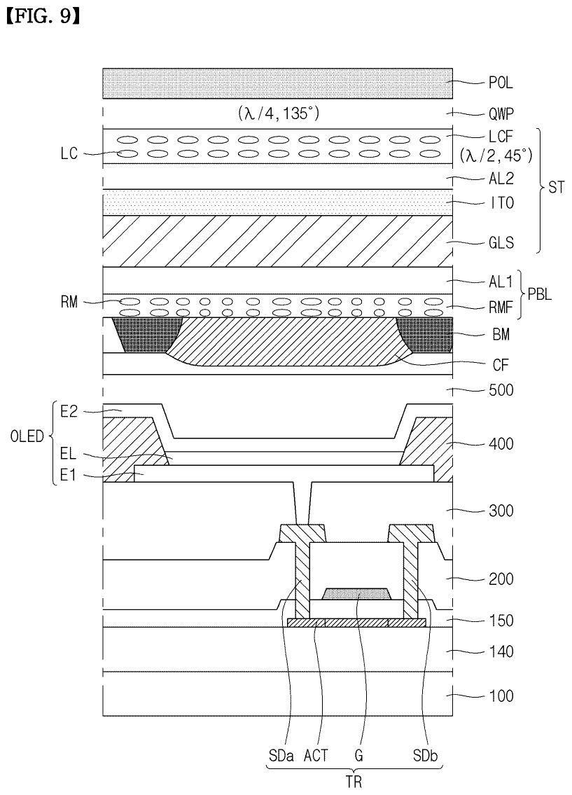

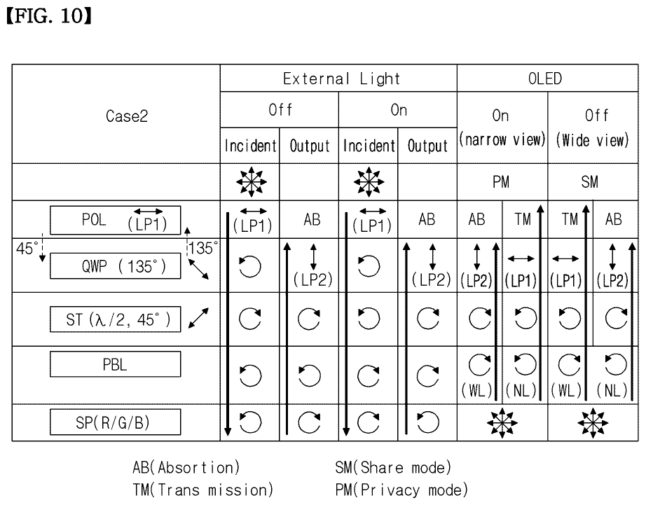

FIG. 9 is a sectional view illustrating a second embodiment of the structure of the display panel shown in FIG. 1, and FIG. 10 is a view illustrating a change in polarization of the display panel according to FIG. 9.

The description given with reference to FIGS. 1 to 8 is applied to the parts of FIGS. 9 and 10 that duplicate with those of FIGS. 1 to 8, and only the parts of FIGS. 9 and 10 that are different from those of FIGS. 1 to 8 will be described.

As shown in FIG. 9, the display panel according to the second embodiment of the present disclosure may include a substrate 100, a buffer layer 140, a gate insulating film 150, an interlayer insulating film 200, a planarization film 300, a transistor TR, a bank 400, and a light-emitting element OLED, an encapsulation layer 500, a black matrix BM, a color filter CF, a Pancharatnam-Berry lens PBL, an active shutter ST, a quarter wave plate QWP, and a polarizer POL.

In the display panel according to the second embodiment of the present disclosure, the description given with reference to FIGS. 3 to 8 is applied to the substrate 100, the buffer layer 140, the gate insulating film 150, the interlayer insulating film 200, the planarization film 300, the transistor TR, the bank 400, the light-emitting element OLED, the encapsulation layer 500, the black matrix BM, the color filter CF, the Pancharatnam-Berry lens PBL, and the polarizer POL.

The quarter wave plate QWP may be disposed between the polarizer POL and the active shutter ST. The quarter wave plate QWP may have an optical axis of 135° and may phase-delay incident light by ¼ wavelength (λ). Accordingly, the quarter wave plate QWP may convert linear polarization into circular polarization and may convert circular polarization into linear polarization.

The active shutter ST according to the second embodiment of the present disclosure may have a rubbing angle of 45° and a phase delay value of ±½ wavelength (λ) according to mode voltage application.

The active shutter ST according to the second embodiment may not delay the wavelength of incident light when the mode control voltage VPM has a turn-on voltage, and may phase-delay the wavelength of the incident light by ½ wavelength when the mode control voltage VPM has a turn-off voltage.

Therefore, when light having circular polarization is incident, the active shutter ST according to the second embodiment may maintain the circular polarization state of the incident light when the mode control voltage VPM has a turn-on voltage, and may reverse the rotation direction of the circular polarization when the mode control voltage VPM has a turn-off voltage.

A polarization change of the display panel according to the second embodiment (case 2) of the present disclosure will be described with reference to FIG. 10.

When isotropic external light is incident on the display panel in the state in which the active shutter ST is off, the isotropic external light may be converted into light having first linear polarization LP1 while passing through the polarizer POL, may be converted into light having right-circular polarization while passing through the quarter wave plate QWP, may be converted into light having left-circular polarization while passing through the turned-off active shutter ST, may be converted into light having right-circular polarization while passing through the Pancharatnam-Berry lens PBL, may be incident on a subpixel SP, and may be converted into light having left-circular polarization while being reflected from the subpixel SP.

The reflected light having the left-circular polarization may be converted into right-circular polarization while passing through the Pancharatnam-Berry lens PBL, may be converted into left-circular polarization while passing through the turned-off active shutter ST, may be converted into second linear polarization LP2 while passing through the quarter wave plate QWP, and may be absorbed (AB) by the polarizer POL.

When isotropic external light is incident on the display panel in the state in which the active shutter ST is on, the isotropic external light may be converted into light having first linear polarization LP1 while passing through the polarizer POL, may be converted into light having right-circular polarization while passing through the quarter wave plate QWP, may be maintained as the right-circular polarization while passing through the turned-on active shutter ST, may be converted into light having left-circular polarization while passing through the Pancharatnam-Berry lens PBL, may be incident on the subpixel SP, and may be converted into right-circular polarization while being reflected from the subpixel SP.

The reflected light having the right-circular polarization may be converted into left-circular polarization while passing through the Pancharatnam-Berry lens PBL, may be maintained as the left-circular polarization while passing through the turned-on active shutter ST, may be converted into second linear polarization LP2 while passing through the quarter wave plate QWP, and may be absorbed (AB) by the polarizer POL.

As described above, the display panel according to the present disclosure is provided with the active shutter ST, whereby it is possible to prevent reflection of external light regardless of the turn-on and turn-off of the active shutter ST.

In the state in which the active shutter ST is on, the Pancharatnam-Berry lens PBL may receive isotropic pixel light emitted from the subpixel SP. The Pancharatnam-Berry lens PBL may receive the isotropic pixel light and may output both a wide view light WL having left-circular polarization and a narrow view light NL having right-circular polarization.

When the mode control voltage VPM has a turn-on voltage, the active shutter ST may maintain the polarization state of the incident light without delaying the wavelength of the incident light.

Accordingly, the wide view light WL having the left-circular polarization may be maintained as the left-circular polarization while passing through the turned-on active shutter ST, may be converted into light having second linear polarization LP2 while passing through the quarter wave plate QWP, and may be absorbed (AB) by the polarizer POL. The narrow view light NL having the right-circular polarization may be maintained as the right-circular polarization while passing through the turned-on active shutter ST, may be converted into light having first linear polarization LP1 while passing through the quarter wave plate QWP, and may be transmitted (TM) through the polarizer POL.

Accordingly, in the state in which the active shutter ST is on, the display panel may prevent the reflection of external light and output narrow view light NL, whereby the display panel may be operated in a privacy mode PM in which the display panel displays a narrow view image.

In addition, in the state in which the active shutter ST is off, the active shutter ST may reverse the rotation direction of circular polarization by phase-delaying the wavelength of the incident light by ½ wavelength when the mode control voltage VPM has a turn-off voltage.

Accordingly, the wide view light WL having the left-circular polarization output from the Pancharatnam-Berry lens PBL may be converted into right-circular polarization while passing through the turned-off active shutter ST, may be converted into light having first linear polarization LP1 while passing through the quarter wave plate QWP, and may be transmitted (TM) through the polarizer POL.

The narrow view light NL having the right-circular polarization output from the Pancharatnam-Berry lens PBL may be converted into left-circular polarization while passing through the turned-on active shutter ST, may be converted into light having second linear polarization LP2 while passing through the quarter wave plate QWP, and may be absorbed (AB) by the polarizer POL.

Accordingly, in the state in which the active shutter ST is on, the display panel may prevent the reflection of external light and output wide view light WL, whereby the display panel may be operated in a share mode SM in which the display panel displays a wide view image.

In FIGS. 3 to 10, the case where the subpixel SP outputs pixel light in a direction toward a front surface of a substrate has been described by way of example, but the present disclosure is not limited thereto, and the same may be equally applied to a bottom emission structure in which the subpixel SP outputs pixel light in a direction toward a rear surface of the substrate.

Hereinafter, an example in which the display panel has a bottom emission structure will be described.

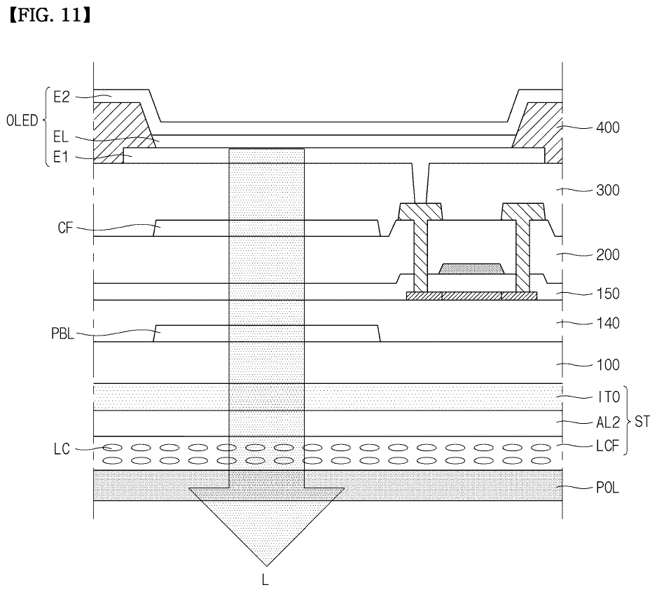

FIG. 11 is a view illustrating an example of the structure of a bottom emission type display panel.

As shown in FIG. 11, the bottom emission type display panel may include a substrate 100, a buffer layer 140, a gate insulating film 150, an interlayer insulating film 200, a planarization film 300, a transistor TR, a bank 400, a light-emitting element OLED, a black matrix (not shown), a color filter CF, a Pancharatnam-Berry lens PBL, an active shutter ST, and a polarizer POL.

The description given with reference to FIGS. 3 to 10 is applied to the parts of FIG. 11 that are identical to those of FIGS. 3 to 10, and only the parts of FIG. 11 that are different from those of FIGS. 3 to 10 will be described.

As shown in FIG. 11, when the display panel has a bottom emission structure, a first electrode E1 of the light-emitting element OLED may be a transparent electrode made of a transparent conductive material (transparent conductive oxide, TCO) such as ITO and IZO. The first electrode E1 may include a metal such as aluminum (Al) or silver (Ag) and may have high reflectivity.

Accordingly, pixel light emitted from an emission layer EL may pass through the substrate 100 and may be output in a direction toward a rear surface of the substrate 100.

When the display panel has a bottom emission structure, as described above, the color filter CF may be located between the interlayer insulating film 200 and the planarization film 300, and the black matrices (not shown) may be located in the state in which the color filter CF is interposed therebetween.

The Pancharatnam-Berry lens PBL may be located between the substrate 100 and the buffer layer 140.

The active shutter ST and the polarizer POL may be located on the rear surface of the substrate 100. A transparent electrode ITO of the active shutter ST may be located on the rear surface of the substrate 100, and a second alignment film AL2, a liquid crystal layer LCF, and the polarizer POL may be sequentially located on the transparent electrode ITO.

The configurations of the Pancharatnam-Berry lens PBL, the active shutter ST, and the polarizer POL according to the first embodiment of the present disclosure or the configurations of the Pancharatnam-Berry lens PBL, the active shutter ST, the quarter wave plate QWP, and the polarizer POL according to the second embodiment of the present disclosure may be equally applied to the bottom emission type display panel shown in FIG. 11.

As is apparent from the above description, according to embodiments of the present disclosure, light output from a light-emitting element is divided into light having a wide viewing angle and light having a narrow viewing angle through a Pancharatnam-Berry lens, the polarization state of the light is changed through an active shutter, and one of the light having the wide viewing angle and the light having the narrow viewing angle is controlled as light to be transmitted through a polarizer, whereby it is possible to control the viewing angle of a display device while minimizing a reduction in luminance.

Effects of the present disclosure are not limited by the above mentioned effects, and more various effects are included in the present disclosure.

Although the embodiments of the present disclosure have been described in more detail with reference to the accompanying drawings, the present disclosure is not necessarily limited to these embodiments, and may be implemented in various ways within the scope of the technical idea of the present disclosure. Consequently, the embodiments of the present disclosure are not intended to limit the technical idea of the present disclosure, but are intended to explain technical idea of the present disclosure, and the scope of the technical idea of the present disclosure is not limited by these embodiments. Therefore, the embodiments described above must be understood as illustrative, not restrictive, in all respects. The scope of protection of the present disclosure should be interpreted based on the claims, and all technical ideas within the equivalent scope should be interpreted as being included in the scope of protection of the present disclosure.

What is claimed is:

1. A display device comprising:
a light-emitting element configured to emit light;
a Pancharatnam-Berry lens disposed on the light-emitting element, the Pancharatnam-Berry lens configured to convert pixel light emitted by the light-emitting element into light having an increasing width and into light having a decreasing width;
an active shutter disposed on the Pancharatnam-Berry lens, the active shutter configured to change a polarization state of light incident from the Pancharatnam-Berry lens differently depending on whether a mode control voltage is applied to the active shutter and to output light with the changed polarization; and
a polarizer disposed on the active shutter, the polarizer configured to transmit or absorb the light output from the active shutter.

2. The display device according to claim 1,
wherein the Pancharatnam-Berry lens converts the pixel light incident from the light-emitting element having a first width into wide view light having first circular polarization rotating in a first direction and a width increasing from the first width, and
the Pancharatnam-Berry lens converts the pixel light into a narrow view light having second circular polarization rotating in a second direction opposite the first direction and a width decreasing from the first width.

3. The display device according to claim 1, wherein the Pancharatnam-Berry lens comprises a reactive mesogen film having reactive mesogen aligned on an alignment film in a predetermined pattern.

4. The display device according to claim 1, wherein the polarizer transmits light having first linear polarization that oscillates in a first direction and absorbs light having second linear polarization that oscillates in a second direction different from the first direction, among light incident from the active shutter.

5. The display device according to claim 1, wherein
the active shutter comprises liquid crystal molecules aligned on an alignment film at a predetermined alignment angle, the alignment angle being changed according to the mode control voltage, and
the liquid crystal molecules have a first alignment angle with respect to the alignment film when the mode control voltage has a turn-off voltage and have a second alignment angle different from the first alignment angle with respect to the alignment film when the mode control voltage has a turn-on voltage.

6. The display device according to claim 5, wherein
when the mode control voltage has the turn-off voltage, the active shutter outputs incident light in a state in which a wavelength of the incident light is delayed by a first phase by causing the liquid crystal molecules to have the first alignment angle, and
when the mode control voltage has the turn-on voltage, the active shutter outputs incident light in a state in which a wavelength of the incident light is delayed by a second phase by causing the liquid crystal molecules to have the second alignment angle.

7. The display device according to claim 1, wherein the active shutter changes the pixel light from circular polarization to linear polarization or reverses a rotation direction of the circular polarization of the pixel light depending on whether the mode control voltage is applied.

8. The display device according to claim 1, wherein
the active shutter phase-delays a wavelength of incident light by ¾ wavelength when the mode control voltage has a turn-off voltage, and
the active shutter phase-delays the wavelength of the incident light by ¼ wavelength when the mode control voltage of a turn-on voltage is applied.

9. The display device according to claim 2, wherein
when the mode control voltage has a turn-off voltage, the active shutter polarizes the first circular polarization into a first linear polarization and converts the second circular polarization into a second linear polarization, and
when the mode control voltage has a turn-on voltage, the active shutter polarizes the first circular polarization into the second linear polarization and converts the second circular polarization into the first linear polarization.

10. The display device according to claim 1, further comprising a quarter wave plate provided between the polarizer and the active shutter.

11. The display device according to claim 10, wherein
the active shutter does not delay a wavelength of incident light when the mode control voltage has a turn-on voltage, and
the active shutter phase-delays the wavelength of the incident light by ½ wavelength when the mode control voltage has a turn-off voltage.

12. The display device according to claim 11, wherein
the active shutter maintains a circular polarization state of incident light having circular polarization when the mode control voltage has a turn-on voltage, and
the active shutter reverses a rotation direction of the circular polarization when the mode control voltage has a turn-off voltage.

13. The display device according to claim 1, wherein
the light-emitting element is disposed on a front surface of a substrate, and
the Pancharatnam-Berry lens, the active shutter, and the polarizer are sequentially disposed on the light-emitting element.

14. The display device according to claim 1, wherein
the light-emitting element is disposed on a front surface of a substrate,
the Pancharatnam-Berry lens is disposed between the light-emitting element and the substrate, and
the active shutter and the polarizer are disposed on a rear surface of the substrate.

15. A display device comprising:
a light-emitting element configured to emit light;
a Pancharatnam-Berry lens disposed on the light-emitting element;
an active shutter disposed on the Pancharatnam-Berry lens, the active shutter configured to change a polarization state of light incident from the Pancharatnam-Berry lens responsive to a mode control voltage applied to the active shutter; and
a polarizer disposed on the active shutter, the polarizer configured to transmit or absorb light output from the active shutter,
wherein the light transmitted through the polarizer has a first viewing angle, responsive to the mode control voltage applied to the active shutter being in a first state, and
wherein the light transmitted through the polarizer has a second viewing angle narrower than the first viewing angle, responsive to the mode control voltage applied to the active shutter being in a second state different from the first state.

16. The display device according to claim 15,
wherein the Pancharatnam-Berry lens converts the light incident from the light-emitting element having a first width into wide view light having first circular polarization rotating in a first direction and a width increasing from the first width, and
the Pancharatnam-Berry lens converts the light incident from the light-emitting element into a narrow view light having second circular polarization rotating in a second direction opposite the first direction and a width decreasing from the first width.

17. The display device according to claim 15, wherein the polarizer transmits light having first linear polarization that oscillates in a first direction and absorbs light having second linear polarization that oscillates in a second direction different from the first direction, among light incident from the active shutter.

18. The display device according to claim 15, wherein
the active shutter comprises liquid crystal molecules aligned on an alignment film at a predetermined alignment angle, the alignment angle being changed according to the mode control voltage, and
the liquid crystal molecules have a first alignment angle with respect to the alignment film when the mode control voltage is in the first state and have a second alignment angle different from the first alignment angle with respect to the alignment film when the mode control voltage is in the second state.

19. The display device according to claim 15, wherein the active shutter changes the light incident from the light-emitting element from circular polarization to linear polarization or reverses a rotation direction of the circular polarization of the pixel light depending on the state of the mode control voltage.

20. The display device according to claim 15, further comprising a quarter wave plate provided between the polarizer and the active shutter.
